(19) United States
(12) Patent Application Publication
(10) Pub. No.: US 2019/0033714 A1
(43) Pub. Date: Jan. 31, 2019

(54) RESIN COMPOSITION, CURED RELIEF PATTERN THEREOF, AND METHOD FOR MANUFACTURING SEMICONDUCTOR ELECTRONIC COMPONENT OR SEMICONDUCTOR EQUIPMENT USING THE SAME

(71) Applicant: TORAY INDUSTRIES, INC., Tokyo (JP)

(72) Inventors: Osamu BABA, Otsu-shi (JP); Makoto HAYASAKA, Otsu-shi (JP); Ryoji OKUDA, Otsu-shi (JP)

(73) Assignee: TORAY INDUSTRIES, INC., Tokyo (JP)

(21) Appl. No.: 16/073,248

(22) PCT Filed: Jan. 24, 2017
(86) PCT No.: PCT/JP2017/002286

§ 371 Date: Jul. 26, 2018

(30) Foreign Application Priority Data
Mar. 28, 2016 (JP) 2016-063639

(51) Int. Cl. G03F 7/023; C08L 79/08; G03F 7/20; C08L 61/06

(52) U.S. Cl. CPC G03F 7/023; C08L 79/08; C08L 2203/206; C08L 61/06; C08L 2203/16; G03F 7/2012

(57) ABSTRACT

An object of the present invention is to provide a resin composition capable of suppressing surface roughness in a thin film portion and maintaining insulation reliability of a thin film portion, a cured relief pattern of the resin composition, and a method for manufacturing a semiconductor electronic component or a semiconductor equipment using the cured relief pattern. The constitution of the present invention for achieving the above-mentioned object is as follows. That is, the present invention provides a resin composition containing: (a) at least one resin selected from an alkali-soluble polyimide, an alkali-soluble polybenzoxazole, an alkali-soluble polyamide-imide, precursors thereof, and copolymers thereof; and (b) an alkali-soluble phenol resin, wherein a ratio (R_{b}/Rₐ) between an alkali dissolution rate (Rₐ) of the resin (a) and an alkali dissolution rate (R_{b}) of the resin (b) satisfies a relationship of 0.5≤R_{b}/Rₐ≤2.0. The present invention also provides a cured relief pattern of the resin composition, and a method for manufacturing a semiconductor electronic component or a semiconductor equipment using the cured relief pattern.

### TECHNICAL FIELD

The present invention relates to a resin composition, a cured relief pattern of the resin composition, and a method for manufacturing a semiconductor electronic component or a semiconductor equipment using the cured relief pattern. More particularly, the present invention relates to a resin composition suitably used in a protective film for a semiconductor device, an interlayer insulating film, an insulation layer of an organic electroluminescent device, and the like.

### BACKGROUND ART

In a protective film for a semiconductor device, an interlayer insulating film, an insulation layer of an organic electroluminescent device, and a planarization film for a TFT substrate, a polyimide resin, a polybenzoxazole resin, and a polyamide-imide resin that are excellent in heat resistance, mechanical characteristics and the like are widely used. A conventionally employed method is a method in which, first, a coating film of a heat-resistant resin precursor having high solubility in an organic solvent is formed, then the coating film is subjected to patterning with use of a photoresist mainly containing a novolak resin or the like, and the precursor is thermally cured into a heat-resistant resin that is insoluble and infusible.

In recent years, such a photoresist process is simplified with use of a negative or positive photosensitive resin composition that is patternable by itself.

In general, in the case where such a photosensitive resin composition is used, either of an exposed portion and an unexposed portion is removed by development to expose the foundation layer. There has also been proposed a method of forming a relief pattern having a plurality of levels of thicknesses by exposing a coating film of a positive photosensitive resin composition to light through a half-tone mask, or exposing such a coating film to light a plurality of times with different masks or different exposure energies, and then developing the coating film.

Further, for the purpose of improving the throughput, improvement in the sensitivity of the photosensitive resin composition has been studied, and there is a method of mixing a phenolic hydroxyl group-containing resin such as a novolak resin or a polyhydroxystyrene resin in a heat-resistant resin or a precursor thereof. Specific examples of such a mixture include a positive photosensitive resin precursor composition containing 101 parts by weight or more of a novolak resin and/or a polyhydroxystyrene resin based on 100 parts by weight of a polyimide precursor or a polybenzoxazole precursor, and a quinone diazide compound (see Patent Document 1), and a photosensitive resin composition containing a polyimide resin, a phenolic hydroxyl group-containing resin, a photo acid generator, and a crosslinking agent (see Patent Document 2).

### PRIOR ART DOCUMENTS

### Patent Documents

Patent Document 1: Japanese Patent Laid-open Publication No. 2005-352004 (pp. 1-3)

Patent Document 2: Japanese Patent Laid-open Publication No. 2008-83359 (pp. 1-3)

### SUMMARY OF THE INVENTION

### Problems to be Solved by the Invention

However, in the case of forming a relief pattern having a plurality of levels on a coating film of such a resin composition by the above-mentioned method, there are problems that the surface of a thin film portion having a thickness of 0.1 μm or more and 3.0 μm or less is roughened and the coating film has a poor appearance, and the coating film is deteriorated in insulation reliability due to electric field concentration on the local thin film portion.

The present invention has been made in view of the above-mentioned problems, and an object of the present invention is to provide a resin composition capable of suppressing surface roughness in a thin film portion and maintaining insulation reliability of a thin film portion, a cured relief pattern of the resin composition, and a method for manufacturing a semiconductor electronic component or a semiconductor equipment using the cured relief pattern.

### Solutions to the Problems

In order to solve the above-mentioned problems, the resin composition of the present invention has the following constitution.

[1] A resin composition containing:

(a) at least one resin selected from an alkali-soluble polyimide, an alkali-soluble polybenzoxazole, an alkali-soluble polyamide-imide, precursors thereof, and copolymers thereof; and

(b) an alkali-soluble phenol resin,

wherein a ratio (R_{b}/Rₐ) between an alkali dissolution rate (Rₐ) of the resin (a) and an alkali dissolution rate (R_{b}) of the resin (b) satisfies a relationship of 0.5≤R_{b}/Rₐ≤2.0.

[2] The resin composition according to [1], wherein the ratio (R_{b}/Rₐ) between the alkali dissolution rate (Rₐ) of the resin (a) and the alkali dissolution rate (R_{b}) of the resin (b) satisfies a relationship of 0.8≤R_{b}/Rₐ<1.0.

[3] The resin composition according to [1] or [2], further containing (c) a quinone diazide compound and having photosensitivity.

[4] The resin composition according to any one of [1] to [3], wherein the resin (b) has a weight average molecular weight of 1,000 or more and 30,000 or less.

[5] The resin composition according to any one of [1] to [4], wherein the alkali dissolution rate (Rₐ) of the resin (a) is 1,000 nm/min or more and 20,000 nm/min or less.

[6] The resin composition according to any one of [1] to [5], wherein the resin (a) contains a structural unit represented by the general formula (1) in an amount of 50% or more and 100% or less of a total of all structural units:

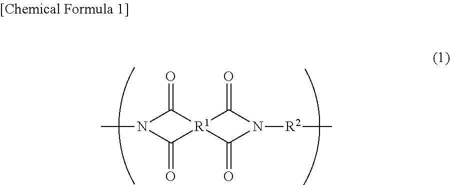

wherein R¹ represents a tetravalent organic group, and R² represents a divalent organic group.

[7] The resin composition according to any one of [1] to [6], wherein the resin (a) has 2.0 mol/kg or more and 3.5 mol/kg or less of a phenolic hydroxyl group.

[8] The resin composition according to any one of [1] to [7], wherein the resin (a) has a weight average molecular weight of 18,000 or more and 30,000 or less.

[9] The resin composition according to any one of [1] to [8], wherein the resin (b) contains at least one of a structural unit represented by the formula (2) and a structural unit represented by the formula (3) in an amount of 50% or more and 95% or less of a total of all structural units:

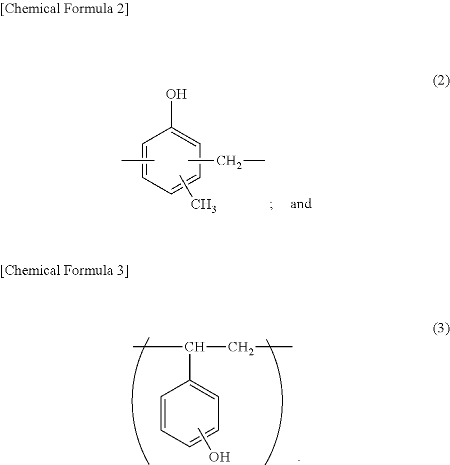

[10] A cured relief pattern that is a cured product of the resin composition according to any one of [1] to [9].

[11] The cured relief pattern according to [10], wherein at least a part of an exposed portion has a film thickness that is 5% or more and 50% or less of a film thickness of an unexposed portion.

[12] The cured relief pattern according to [10] or [11], having a breakdown voltage per a film thickness of 1 mm of 200 kV or more at a position where the cured relief pattern has a film thickness of 0.1 μm or more and 3.0 μm or less.

[13] A method for manufacturing a cured relief pattern, the method including the steps of:

applying the resin composition according to any one of [1] to [9] to a substrate and drying the resin composition to form a resin film;

exposing the resin film to light through a mask;

developing the exposed resin film to form a relief pattern; and

heating and curing the developed relief pattern,

wherein the step of heating and curing the developed relief pattern includes a step of forming a cured relief pattern in which at least a part of an exposed portion has a film thickness that is 5% or more and 50% or less of a film thickness of an unexposed portion.

[14] An interlayer insulating film or a semiconductor protective film, including the cured relief pattern according to any one of [10] to [12].

[15] A method for manufacturing an interlayer insulating film or a semiconductor protective film using the cured relief pattern according to any one of [10] to [12] or a cured relief pattern manufactured by the method according to [13].

[16] A semiconductor electronic component or a semiconductor equipment, including the cured relief pattern according to any one of [10] to [12].

[17] A method for manufacturing a semiconductor electronic component or a semiconductor equipment using the cured relief pattern according to any one of [10] to [12] or a cured relief pattern manufactured by the method according to [13].

### Effects of the Invention

The resin composition of the present invention is capable of suppressing surface roughness in a thin film portion and maintaining insulation reliability of a thin film portion, and is also capable of providing a cured relief pattern of the resin composition as well as a semiconductor electronic component or a semiconductor equipment including the cured relief pattern.

### EMBODIMENTS OF THE INVENTION

The resin composition of the present invention is a resin composition containing: (a) at least one resin selected from an alkali-soluble polyimide, an alkali-soluble polybenzoxazole, an alkali-soluble polyamide-imide, precursors thereof, and copolymers thereof; and (b) an alkali-soluble phenol resin, wherein a ratio (R_{b}/Rₐ) between an alkali dissolution rate (Rₐ) of the resin (a) and an alkali dissolution rate (R_{b}) of the resin (b) satisfies a relationship of 0.5≤R_{b}/Rₐ≤2.0.

The alkali dissolution rate in the present invention is measured by the following method.

A resin is dissolved in γ-butyrolactone so that the resulting solution would have a solid content concentration of 35% by mass. The solution is applied to a 6-inch silicon wafer and prebaked on a hot plate at 120° C. for 4 minutes to form a prebaked film having a thickness of 10 μm±0.5 μm. The prebaked film is immersed in a 2.38% by mass aqueous tetramethylammonium hydroxide solution at 23±1° C. for 1 minute. The thickness of the dissolved portion of the film is calculated from the film thicknesses before and after immersion, and the thickness of the film dissolved per minute is defined as the alkali dissolution rate. When the resin film is completely dissolved within less than 1 minute, the time required for dissolution is measured, and the thickness of the film dissolved per minute is determined from the obtained time and the film thickness before immersion. The result is defined as the alkali dissolution rate. When the resin is a mixture of two or more resins, the alkali dissolution rate may be measured using the resin mixture having a content ratio among such resins.

The “alkali-soluble” resin in the present invention means a resin having an alkali dissolution rate of 60 nm/min or more and 1,000,000 nm/min or less as measured by the above-mentioned method.

In the present invention, the ratio (R_{b}/Rₐ) between the alkali dissolution rate (Rₐ) of the resin of the component (a) and the alkali dissolution rate (R_{b}) of the resin of the component (b) is important for suppressing the surface roughness in the thin film portion. A possible mechanism therefor will be described below.

The thin film portion in the present invention is formed by moderately dissolving the film during the development. In the development, if the alkali dissolution rate is greatly different between the resin of the component (a) and the resin of the component (b), only the resin having a higher alkali dissolution rate dissolves quickly. Although an effect of dissolving the other resin simultaneously is exerted as illustrated by the stone wall model, a residue of the resin having a lower alkali dissolution rate appears as surface roughness on the thin film portion. When the alkali dissolution rates of the resin of the component (a) and the resin of the component (b) are unified within an appropriate range, the resins uniformly dissolve during the development, and the generation of roughness can be suppressed.

In the case where the resin composition is used as a positive photosensitive resin composition, the film thickness of the thin film portion after curing is preferably 0.1% or more, more preferably 1% or more, still more preferably 5% or more, particularly preferably 10% or more of the film thickness of the unexposed portion from the viewpoint of forming a moderate level difference. Meanwhile, the film thickness of the thin film portion is preferably 99% or less, more preferably 90% or less, still more preferably 70% or less, even more preferably 50% or less, particularly preferably 40% or less of the film thickness of the unexposed portion.

In the case where the resin composition is used as a negative photosensitive resin composition, the film thickness of the thin film portion after curing is preferably 0.1% or more, more preferably 1% or more, still more preferably 5% or more, particularly preferably 10% or more of the film thickness of the 100% exposed portion from the viewpoint of forming a moderate level difference. Meanwhile, the film thickness of the thin film portion is preferably 99% or less, more preferably 90% or less, still more preferably 70% or less, even more preferably 50% or less, particularly preferably 40% or less of the film thickness of the 100% exposed portion.

The resin composition of the present invention contains (a) at least one resin selected from an alkali-soluble polyimide, an alkali-soluble polybenzoxazole, an alkali-soluble polyamide-imide, precursors thereof, and copolymers thereof.

Examples of the polyimide precursor preferably used in the present invention include polyamic acids, polyamic acid esters, polyamic acid amides, and polyisoimides. A polyamic acid can be obtained, for example, by reacting a tetracarboxylic acid, a corresponding tetracarboxylic acid dianhydride, corresponding tetracarboxylic acid diester dichloride or the like with a diamine, a corresponding diisocyanate compound, or a corresponding trimethylsilylated diamine. A polyimide can be obtained, for example, by dehydrating and ring-closing a polyamic acid obtained by the above-mentioned method through heating or chemical treatment with an acid, a base or the like.

Examples of the polybenzoxazole precursor preferably used in the present invention include polyhydroxyamides. polyhydroxyamide can be obtained, for example, by reacting a bisaminophenol with a dicarboxylic acid, a corresponding dicarboxylic acid chloride, a corresponding dicarboxylic acid active ester, or the like. A polybenzoxazole can be obtained, for example, by dehydrating and ring-closing a polyhydroxyamide obtained by the above-mentioned method through heating or chemical treatment with phosphoric anhydride, a base, a carbodiimide compound or the like.

The polyimide-imide precursor preferably used in the, present invention can be obtained, for example, by reacting a tricarboxylic acid, a corresponding tricarboxylic acid anhydride, a corresponding tricarboxylic acid anhydride halide or the like with a diamine or a diisocyanate. A polyamide-imide can be obtained, for example, by dehydrating and ring-closing a precursor obtained by the above-mentioned method through heating or chemical treatment with an acid, a base or the like.

Furthermore, it is more preferable that the resin of the component (a) be obtained, after completion of the polymerization, by precipitation in a poor solvent for the polymer, such as methanol or water, followed by washing and drying. Since the low molecular weight components and the like of the polymer can be removed by the reprecipitation, the mechanical characteristics of the composition after thermal curing are greatly improved.

The resin of the component (a) used in the present invention preferably has at least one of the structural units represented by the general formulae (1) and (4) to (6). The component (a) may contain two or more resins having these structural units, or may contain a copolymer of two or more structural units. The resin of the component (a) in the present invention preferably has 3 to 1000 structural units as at least one of the structural units represented by the general formulae (1) and (4) to (6). In particular, the resin of the component (a) particularly preferably has the structural, unit (1) from the viewpoint of mechanical characteristics and chemical resistance of the cured film in low temperature firing at 250° C. or lower. The resin of the component (a) contains the structural unit represented by the general formula (1) preferably in an amount of 30% or more, more preferably 50% or more, still more preferably 70% or more, particularly preferably 90% or more of the total of all structural units of the resin of the component (a).

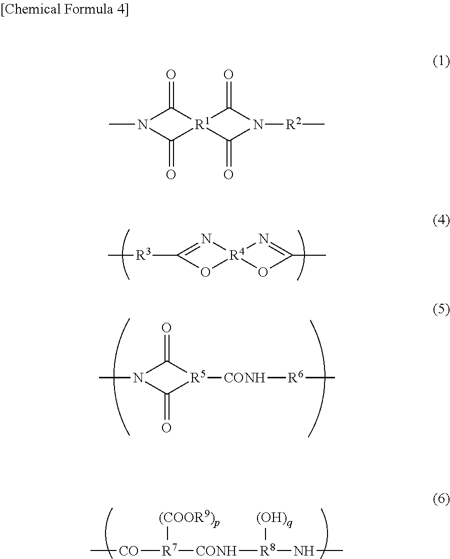

In the general formulae (1) and (4) to (6), R¹ and R⁴ each represent a tetravalent organic group, R², R³, and R⁶ each represent a divalent organic group, R⁵ represents a trivalent organic group, R⁷ represents a divalent to tetravalent organic group, and R⁸ represents a divalent to 12-valent organic group. R⁹ represents a hydrogen atom or a monovalent hydrocarbon group having 1 to 20 carbon atoms. p represents an integer of 0 to 2, and q represents an integer of 0 to 10.

In the general formulae (1) and (4) to (6), R¹ represents a tetracarboxylic acid derivative residue, R³ represents a dicarboxylic acid derivative residue, R⁵ represents a tricarboxylic acid derivative residue, and R⁷ represents a di-, tri- or tetra-carboxylic acid derivative residue. Examples of acid components that constitute R¹, R³, R⁵, and R⁷(COOR⁹)ₚ include: dicarboxylic acids such as terephthalic acid, isophthalic acid, diphenyl ether dicarboxylic acid, bis (carboxyphenyl) hexafluoropropane, biphenyldicarboxylic acid, benzophenone dicarboxylic acid, and triphenyldicarboxylic acid, tricarboxylic acids such as trimellitic acid, trimesic acid, diphenyl ether tricarboxylic acid, and biphenyltricarboxylic acid, and tetracarboxylic acids such as aromatic tetracarboxylic acids including pyromellitic acid, 3,3′,4,4′-biphenyltetracarboxylic acid, 2,3,3′,4′-biphenyltetracarboxylic acid, 2,2′,3,3′-biphenyltetracarboxylic acid, 3,3′,4,4′-benzophenonetetracarboxylic acid, 2,2′,3,3′-benzophenonetetracarboxylic acid, 2,2-bis (3,4-dicarboxyphenyl)hexafluoropropane, 2,2-bis(2,3-dicarboxyphenyl)hexafluorbpropane, 1,1-bis(3,4-dicarboxyphenyl)ethane, 1,1-bis(2,3-dicarboxyphenyl)ethane, bis(3,4-dicarboxyphenyl)methane, bis(2,3-dicarboxyphenyl)methane, bis(3,4-dicarboxyphenyl)sulfone, bis(3,4-dicarboxyphenyl)ether, 1,2,5,6-naphthalenetetracarboxylic acid, 2,3,6,7-naphthalenetetracarboxylic acid, 2,3,5,6-pyridinetetracarboxylic acid, and 3,4,9,10-perylenetetracarboxylic acid, and aliphatic tetracarboxylic acids including butane tetracarboxylic acid and 1,2,3,4-cyclopentanetetracarboxylic acid. In the general formula (6), one or two carboxyl groups of each of the tricarboxylic acids and the tetracarboxylic acids correspond to the COOR⁹ group. These acid components can be used as they are, or as acid anhydrides, active esters or the like. Further, two or more of these acid components maybe used in combination.

In the general formulae (1) and (4) to (6), R², R⁴, R⁶, and R⁹ each represent a diamine derivative residue. Examples of diamine components that constitute R², R⁴, R⁶, and R⁸(OH)_{q} include: hydroxyl group-containing diamines such as bis(3-amino-4-hydroxyphenyl)hexafluoropropane, bis(3-amino-4-hydroxyphenyl)sulfone, bis(3-amino-4-hydroxyphenyl)propane, bis(3-amino-4-hydroxyphenyl)methylene, bis(3-amino-4-hydroxyphenyl)ether, bis(3-amino-4-hydroxy)biphenyl, and bis(3-amino-4-hydroxyphenyl)fluorene, sulfonic acid-containing diamines such as 3-sulfonic acid-4,4′-diaminodiphenyl ether, thiol group-containing diamines such as dimercaptophenylenediamine, aromatic diamines such as 3,4′-diaminodiphenyl ether, 4,4′-diaminodiphenyl ether, 3,4′-diaminodiphenylmethane, 4,4′-diaminodiphenylmethane, 3,4′-diaminodiphenyl sulfone, 4,4′-diaminodiphenyl sulfone, 3,4′-diaminodiphenyl sulfide, 4,4′-diaminodiphenyl sulfide, 1,4-bis(4-aminophenoxy)benzene, benzine, m-phenylenediamine, p-phenylenediamine, 1,5-naphthalenediamine, 2,6-naphthalenediamine, bis(4-aminophenoxyphenyl)sulfone, bis(3-aminophenoxyphenyl)sulfone, bis(4-aminophenoxy)biphenyl, bis{4-(4-aminophenoxy)phenyl}ether, 1,4-bis(4-aminophenoxy)benzene, 2,2′-dimethyl-4,4′-diaminobiphenyl, 2,2′-diethyl-4,4′-diaminobiphenyl, 3,3′-dimethyl-4,4′-diaminobiphenyl, 3,3′-diethyl-4,4′-diaminobiphenyl, 2,2′,3,3′-tetramethyl-4,4′-diaminobiphenyl, 3,3′,4,4′-tetramethyl-4,4′-diaminobiphenyl, and 2,2′-bis (trifluoromethyl) -4,4′-diaminobiphenyl, compounds obtained by partially substituting hydrogen atoms of aromatic rings of these compounds with an alkyl group having 1 to 10 carbon atoms, a fluoroalkyl group, a halogen atom or the like, diamines having nitrogen-containing heteroaromatic rings such as 2,4-diamino-1,3,5-triazine (guanamine), 2,4-diamino-6-methyl-1,3,5-triazine (acetoguanamine), and 2,4-diamino-6-phenyl-1,3,5-triazine (benzoguanamine), silicone diamines such as 1,3-bis (3-aminopropyl) -1,1,3,3-tetramethyldisiloxane, 1,3-bis (p-aminophenyl) -1,1,3,3-tetramethyldisiloxane, 1,3-bis (p-aminophenethyl) -1,1,3,3-tetramethyldisiloxane, and 1,7-bis (p-aminophenyl) -1,1,3,3,5,5,7,7-octamethyltetrasiloxane, alicyclic diamines such as cyclohexyldiamine and methylenebiscyclohexylamine, and aliphatic diamines. Examples of a diamine containing a polyethylene oxide group include “Jeffamine” (registered trademark) KH-511, Jef famine ED-600, Jeffamine ED-900, Jeffamine ED-2003, Jeffamine EDR-148, Jeffamine EDR-176, and polyoxypropylene diamines D-200, D-400, D-2000, and D-4000 (trade names, available from HUNTSMAN). These diamines can be used as they are, or as corresponding diisocyanate compounds or corresponding trimethylsilylated diamines. Further, two or more of these diamine components may be used in combination. In applications where heat resistance is required, it is preferable to use aromatic diamines in an amount of 50 mol % or more of the whole diamines.

R¹ to R⁸ in the general formulae (1) and (4) to (6) can include a phenolic hydroxyl group, a sulfonic acid group, a thiol group, or the like in their skeletons. Use of a resin moderately including a phenolic hydroxyl group, a sulfonic acid group, or a thiol group provides a photosensitive resin composition excellent in alkali solubility and pattern formability.

The resin of the component (a) preferably has, in the structural unit thereof, a phenolic hydroxyl group for acquiring alkali solubility. The introduction amount of the phenolic hydroxyl group into the resin of the component (a) is preferably 1.0 mol/kg or more, more preferably 1.5 mol/kg or more, still more preferably 2.0 mol/kg or more, particularly preferably 2.2 mol/kg or more from the viewpoint of imparting alkali solubility, and is preferably 5.0 mol/kg or less, more preferably 4.0 mol/kg or less, still more preferably 3.5 mol/kg or less, particularly preferably 3.2 mol/kg or less from the viewpoint of chemical resistance of the cured film.

Further, the resin of the component (a) preferably has, in the structural unit thereof, a fluorine atom. The fluorine atom imparts water repellency to the, surface of the film during alkali development, so that penetration or the like from the surface can be suppressed.

The fluorine atom content in the resin of the component (a) is preferably 10% by mass or more for imparting a sufficient effect of preventing the interfacial penetration, and is preferably 20% by mass or less from the viewpoint of solubility in an alkali aqueous solution.

An aliphatic group having a siloxane structure may be copolymerized with at least one of R², R⁶, and R⁸ as long as the heat resistance is not lowered. Such an aliphatic group may improve the adhesion properties of the resin composition to the substrate. Specific examples of the diamine component include those copolymerized with 1 to 10 mol % of bis (3-aminopropyl)tetramethyldisiloxane, bis (p-aminophenyl) octamethylpentasiloxane or the like.

Further, in order to improve the storage stability of the resin composition, the resin of the component (a) is preferably capped, at an end of the main chain thereof, with an end-capping agent such as a monoamine, an acid anhydride, a monocarboxylic acid, a monoacid chloride compound, or a mono-active ester compound. For the purpose of improving the chemical resistance of the cured film of the resin obtained by firing the resin composition, a monoamine, an acid anhydride, a monocarboxylic acid, a monoacid chloride compound, or a mono-active ester compound having at least one alkenyl group or alkynyl group can also be used as the end-capping agent.

The percentage of introduction of the monoamine used as the end-capping agent is preferably 0.1 mol % or more, particularly preferably 5 mol % or more, and is preferably 60 mol % or less, particularly preferably 50 mol % or less based on all the amine components. The percentage of introduction of the acid anhydride, monocarboxylic acid, monoacid chloride compound, or mono-active ester compound used as the end-capping agent is preferably 0.1 mol % or more, particularly preferably 5 mol % or more based on the diamine component. Meanwhile, the percentage is preferably 100 mol % or less, particularly preferably 90 mol % or less from the viewpoint of maintaining a high molecular weight of the resin. A plurality of different end groups may be introduced by reacting a plurality of end-capping agents.

Preferable examples of the monoamine include aniline, 2-ethynylaniline, 3-ethynylaniline, 4-ethynylaniline, 5-amino-8-hydroxyquinoline, 1-hydroxy-7-aminonaphthalene, 1-hydroxy-6-aminonaphthalene, 1-hydroxy-5-aminonaphthalene, 1-hydroxy-4-aminonaphthalene, 2-hydroxy-7-aminonaphthalene, 2-hydroxy-6-aminonaphthalene, 2-hydroxy-5-aminonaphthalene, 1-carboxy-7-aminonaphthalene, 1-carboxy-6-aminonaphthalene, 1-carboxy-5-aminonaphthalene, 2-carboxy-7-aminonaphthalene, 2-carboxy-6-aminonaphthalene, 2-carboxy-5-aminonaphthalene, 2-aminobenzoic acid, 3-aminobenzoic acid, 4-aminobenzoic acid, 4-aminosalicylic acid, 5-aminosalicylic acid, 6-aminosalicylic acid, 2-aminobenzenesulfonic acid, 3-aminobenzenesulfonic acid, 4-aminobenzenesulfonic acid, 3-amino-4,6-dihydroxypyrimidine, 2-aminophenol, 3-aminophenol, 4-aminophenol, 2-aminothiophenol, 3-aminothiophenol, and 4-aminothiophenol. Two or more of these may be used.

Preferable examples of the acid anhydride, monocarboxylic acid, monoacid chloride compound, and mono-active ester compound include acid anhydrides such as phthalic anhydride, maleic anhydride, nadic anhydride, cyclohexanedicarboxylic anhydride, and 3-hydroxyphthalic anhydride, monocarboxylic acids such as 3-carboxyphenol, 4-carboxyphenol, 3-carboxythiophenol, 4-carboxythiophenol, 1-hydroxy-7-carboxynaphthalene, 1-hydroxy-6-carboxynaphthalene, 1-hydroxy-5-carboxynaphthalene, 1-mercapto-7-carboxynaphthalene, 1-mercapto-6-carboxynaphthalene, 1-mercapto-5-carboxynaphthalene, 3-carboxy benzenesulfonic acid, and 4-carboxy benzenesulfonic acid, monoacid chloride compounds in which carboxyl groups of these compounds are converted into an acid chloride, monoacid chloride compounds in which only one carboxyl group of dicarboxylic acids, such as terephthalic acid, phthalic acid, maleic acid, cyclohexanedicarboxylic acid, 1,5-dicarboxynaphthalene, 1,6-dicarboxynaphthalene, 1,7-dicarboxynaphthalene, and 2,6-dicarboxynaphthalene, is converted into an acid chloride, and active ester compounds obtained by reaction of a monoacid chloride compound with N-hydroxybenzotriazole or N-hydroxy-5-norbornene-2,3-dicarboximide. Two or more of these may be used.

The end-capping agent introduced into the resin of the component (a) can be easily detected by the following method. The end-capping agent used in the present invention can be easily detected, for example, by dissolving a resin containing the end-capping agent introduced therein in an acidic solution to decompose the resin into an amine component and an acid anhydride component that are constituent units of the resin, and analyzing the components by gas chromatography (GC) or nuclear magnetic resonance (NMR). Alternatively, it is also possible to easily detect the end-capping agent by directly analyzing a resin component containing the end-capping agent introduced therein through pyrolysis gas chromatography (PGC), infrared spectral measurement, or ¹³C-NMR spectral measurement.

In the resin having a structural unit represented by any one of the general formulae (1), (4), and (5), the number of repetitions of the structural unit is preferably 3 or more and 200 or less. Further, in the resin having a structural unit represented by the general formula (6), the number of repetitions of the structural unit is preferably 10 or more and 1000 or less. When the number of repetitions is within the above-mentioned range, a thick film can be easily formed.

The resin of the component (a) used in the present invention may consist only of the structural unit represented by any one of the general formulae (1) and (4) to (6), or may be a copolymer or a mixture with other structural units. In the latter case, the content of the structural unit represented by any one of the general formulae (1) and (4) to (6) is preferably 10% by mass or more, more preferably 30% by mass or more in the whole resin. Above all, the resin of the component (a) preferably contains 20 to 200, more preferably 30 to 150 structural units of the general formula (1) from the viewpoint of heat resistance in low temperature firing and storage stability. The type and amount of the structural units used in copolymerization or mixing are preferably selected so that the mechanical characteristics of the thin film obtained by the final heat treatment will not be impaired. Examples of such a main chain skeleton include benzimidazole and benzothiazole.

When a polyimide and/or a precursor thereof is used as the resin of the component (a), a resin having a molar ratio of imide ring-closed units to all the imide and imide precursor units, which is defined as an imide ring closure rate (R_{IM} (%)) in the entire range of 0% or more and 100% or less can be used. However, the R_{IM} is preferably 30% or more, more preferably 50% or more, still more preferably 70% or more, particularly preferably 90% or more from the viewpoint of mechanical characteristics and chemical resistance of the cured film in low temperature firing at 250° C. or lower.

The imide ring closure rate (R_{IM} (%)) can be easily obtained, for example, by the following method. First, the infrared absorption spectrum of a polymer is measured to confirm the presence of absorption peaks (around 1780 cm⁻¹ and around 1377 cm⁻¹) of the imide structure attributable to the polyimide, and the peak intensity (X) around 1377 cm⁻¹ is obtained. Then, the polymer is heat-treated at 350° C. for 1 hour, the infrared absorption spectrum of the polymer is measured, and the peak intensity (Y) around 1377 cm⁻¹ is obtained. The peak intensity ratio between them corresponds to the content of imide groups in the polymer before heat treatment, that is, the imide ring closure rate (R_{IM}=X/Y×100(%)).

The alkali dissolution rate (Rₐ) of the resin of the component (a) preferably used in the present invention is preferably 100 nm/min or more, more preferably 200 nm/min or more, still more preferably 500 nm/min or more, particularly preferably 1,000 nm/min or more from the viewpoint of shortening the developing time, and is preferably 200,000 nm/min or less, more preferably 100,000 nm/min or less, still more preferably 50,000 nm/min or less, even more preferably 20,000 nm/min or less, particularly preferably 15,000 nm/min or less from the viewpoint of achieving a satisfactory pattern shape.

A preferable weight average molecular weight of the resin of the component (a) can be determined in terms of polystyrene by gel permeation chromatography (GPC). The weight average molecular weight is preferably 2,000 or more, more preferably 5,000 or more, still more preferably 10,000 or more from the viewpoint of mechanical characteristics of the cured film, and is preferably 100,000 or less, more preferably 50,000 or less, still more preferably 30,000 or less, particularly preferably 27,000 or less from the viewpoint of alkali solubility.

The resin composition of the present invention contains (b) an alkali-soluble phenol resin. Examples of the resin of the component (b) include a novolak resin, a resole resin, a benzyl ether type phenol resin, and a polyhydroxystyrene resin that are alkali-soluble, but the resin is not limited thereto. Two or more of these may be used. The resin of the component (b) preferably has at least one of the structural units represented by the formulae (2) and (3) from the viewpoint of improving the sensitivity when the resin is used in a photosensitive resin composition. The total amount of these structural units in the total of all structural units is preferably 30% or more, more preferably 50% or more, still more preferably 70% or more, and is preferably 100% or less, more preferably 95% or less, still more preferably 90% or less from the viewpoint of achieving an appropriate dissolution rate.

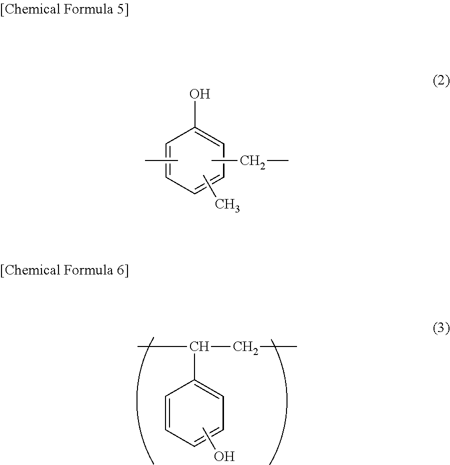

The novolak resin, resole resin, and benzyl ether type phenol resin used as the resin of the component (b) can be obtained by polycondensation of a phenol with an aldehyde such as formalin by a known method.

Examples of the phenol include phenol, p-cresol, m-cresol, o-cresol, 2,3-dimethylphenol, 2,4-dimethylphenol, 2,5-dimethylphenol, 2,6-dimethylphenol, 3,4-dimethylphenol, 3,5-dimethylphenol, 2,3,4-trimethylphenol, 2,3,5-trimethylphenol, 3,4,5-trimethylphenol, 2,4,5-trimethylphenol, methylene bisphenol, methylene bis(p-cresol), resorcin, catechol, 2-methylresorcin, 4-methylresorcin, o-chlorophenol, m-chlorophenol, p-chlorophenol, 2,3-dichlorophenol, m-methoxyphenol, p-methoxyphenol, p-butoxyphenol, o-ethylphenol, m-ethylphenol, p-ethylphenol, 2,3-diethylphenol, 2,5-diethylphenol, p-isopropylphenol, α-naphthol, and β-naphthol. Two or more of these may be used.

Examples of the aldehyde include formalin, paraformaldehyde, acetaldehyde, benzaldehyde, hydroxybenzaldehyde, and chloroacetaldehyde. Two or more of these may be used.

The polyhydroxystyrene resin used as the resin of the component (b) can be obtained, for example, by addition polymerization of a phenol derivative having an unsaturated bond by a known method. Examples of the phenol derivative having an unsaturated bond include hydroxystyrene, dihydroxystyrene, allylphenol, coumaric acid, 2′-hydroxychalcone, N-hydroxyphenyl-5-norbornene-2,3-dicarboxylic acid imide, resveratrol, and 4-hydroxystilbene, and two or more of these may be used. The polyhydroxystyrene resin may also be a copolymer with a monomer containing no phenolic hydroxyl group, such as styrene. In this case, the alkali dissolution rate can be easily adjusted.

A preferable weight average molecular weight of the resin of the component (b) can be determined in terms of polystyrene by gel permeation chromatography (GPC). The weight average molecular weight is preferably 500 or more, more preferably 700 or more, still more preferably 1,000 or more from the viewpoint of chemical resistance, and is preferably 50,000 or less, more preferably 40,000 or less, still more preferably 30,000 or less, particularly preferably 20,000 or less from the viewpoint of alkali solubility.

The content of the resin of the component (b) is preferably 5 parts by mass or more, more preferably 10 parts by mass or more, still more preferably 20 parts by mass or more, particularly preferably 30 parts by mass or more based on 100 parts by mass of the resin of the component (a) from the viewpoint of improving the sensitivity when the resin is used in a photosensitive resin composition, and is preferably 1, 000 parts by mass or less, more preferably 500 parts by mass or less, still more preferably 200 parts by mass or less, particularly preferably 100 parts by mass or less from the viewpoint of heat resistance of the cured film.

The alkali dissolution rate (R_{b}) of the resin of the component (b) preferably used in the present invention is preferably 100 nm/min or more, more preferably 200 nm/min or more, still more preferably 500 nm/min or more, particularly preferably 1,000 nm/min or more, and is preferably 200,000 nm/min or less, more preferably 100,000 nm/min or less, still more preferably 50,000 nm/min or less, even more preferably 20,000 nm/min or less, particularly preferably 15,000 nm/min or less from the viewpoint of achieving an appropriate developing time.

The ratio (R_{b}/Rₐ) between the alkali dissolution rate (Rₐ) of the resin of the component (a) and the alkali dissolution rate (R_{b}) f the resin of the component (b) in the present invention is 0.5 or more and 2.0 or less. When the ratio is 0.5 or more, roughness in the thin film portion can be suppressed. The ratio is preferably 0.6 or more, more preferably 0.7 or more, still more preferably 0.8 or more, particularly preferably 0.9 or more from the viewpoint of further suppressing the roughness in the thin film portion and exhibiting high insulation reliability. Similarly, when the ratio is 2.0 or less, roughness in the thin film portion can be suppressed. The ratio is preferably 1.8 or less, more preferably 1.5 or less, still more preferably 1.2 or less, even more preferably 1.0 or less, particularly preferably less than 1.0 from the viewpoint of further suppressing the roughness in the thin film portion and exhibiting high insulation reliability.

The resin composition of the present invention preferably contains (c) a quinone diazide compound. When the resin composition contains a quinone diazide compound, an acid is generated in a portion exposed to ultraviolet rays, and the solubility of the exposed portion in an alkali aqueous solution is improved, so that a positive pattern can be obtained by alkali development after exposure to ultraviolet rays.

The resin composition of the present invention preferably contains two or more quinone diazide compounds as the compound (c). In this case, it is possible to further increase the ratio of dissolution rate between the exposed portion and the unexposed portion, and to provide a positive photosensitive resin composition with high sensitivity.

Examples of the compound (c) used in the present invention include those obtained by ester bonding of a sulfonic acid of quinone diazide to a polyhydroxy compound, those obtained by sulfonamide bonding of a sulfonic acid of quinone diazide to a polyamino compound, and those obtained by ester bonding and/or sulfonamide bonding of a sulfonic acid of quinone diazide to a polyhydroxy polyamino compound. It, is not necessary that all the functional groups of these polyhydroxy compound and polyamino compound be substituted with quinone diazide, but it is preferable that 50 mol % or more of all the functional groups be substituted with quinone diazide. Use of such a quinone diazide compound makes it possible to give a positive photosensitive resin composition sensitive to i-line (365 nm), h-line (405 nm), and g-line (436 nm) of a mercury lamp that are general ultraviolet rays.

In the present invention, both a 5-naphthoquinone diazide sulfonyl group and a 4-naphthoquinone diazide sulfonyl group are preferably used as the quinone diazide compound. A compound having both of these groups in one molecule may be used, or compounds having different groups may be used in combination.

The compound (c) used in the present invention can be synthesized by a known method. An example of the method is a method of reacting 5-naphthoquinone diazide sulfonyl chloride with a polyhydroxy compound in the presence of triethylamine.

The content of the compound (c) used in the present invention is preferably 1 to 60 parts by mass based on 100 parts by mass of the resin of the component (a). When the content of the quinone diazide compound is within the above-mentioned range, the sensitivity can be improved, and mechanical characteristics such as elongation of the cured film can be maintained. The content is preferably 3 parts by mass or more in order to further improve the sensitivity, and is preferably 50 parts by mass or less, more preferably 40 parts by mass or less in order not to impair the mechanical characteristics of the cured film. The resin composition may optionally further contain a sensitizer and the like.

The resin composition of the present invention may optionally contain a thermal crosslinking agent. The thermal crosslinking agent is preferably a compound having at least two alkoxymethyl groups and/or methylol groups or a compound having at least two epoxy groups and/or oxetanyl groups, but the thermal crosslinking agent is not limited thereto. When the resin composition contains such a compound, the compound undergoes a condensation reaction with the resin of the component (a) during firing after the patterning to form a crosslinked structure, thereby improving the mechanical characteristics such as elongation of the cured film. Two or more thermal crosslinking agents may be used. In such a case, wider range of designs are made possible.

Preferable examples of the compound having at least two alkoxymethyl groups and/or methylol groups include DML-PC, DML-PEP, DML-OC, DML-OEP, DML-34X, DML-PTBP, DML-PCHP, DML-OCHP, DML-PFP, DML-PSBP, DML-POP, DML-MBOC, DML-MBPC, DML-MTrisPC, DML-BisOC-Z, DML-BisOCHP-Z, DML-BPC, DML-BisOC-P, DMOM-PC, DMOM-PTBP, DMOM-MBPC, TriML-P, TriML-35XL, TML-HQ, TML-BP, TML-pp-BPF, TML-BPE, TML-BPA, TML-BPAF, TML-BPAP, TMOM-BP, TMOM-BPE, TMOM-BPA, TMOM-BPAF, TMOM-BPAP, HML-TPPHBA, HML-TPHAP, HMOM-TPPHBA, and HMOM-TPHAP (trade names, manufactured by Honshu Chemical Industry Co., Ltd.), and “NIKALAC” (registered trademark) MX-290, NIKALAC MX-280, NIKALAC MX-270, NIKALAC MX-279, NIKALAC MW-100LM, and NIKALAC MX-750LM (trade names, manufactured by SANWA Chemical Co., Ltd.), which are available from the respective companies. The resin composition may contain two or more of these.

Preferable examples of the compound having at least two epoxy groups and/or oxetanyl groups include a bisphenol A epoxy resin, a bisphenol A oxetanyl resin, a bisphenol F epoxy resin, a bisphenol F oxetanyl resin, propylene glycol diglycidyl ether, polypropylene glycol diglycidyl ether, and an epoxy group-containing silicone such as polymethyl (glycidyloxypropyl) siloxane, but the compound is not limited thereto. Specific examples thereof include “EPICLON” (registered trademark) 850-S, EPICLON HP-4032, EPICLON HP-7200, EPICLON HP-820, EPICLON HP-4700, EPICLON EXA-4710, EPICLON HP-4770, EPICLON EXA-859CRP, EPICLON EXA-1514, EPICLON EXA-4880, EPICLON EXA-4850-150, EPICLON EXA-4850-1000, EPICLON EXA-4816, and EPICLON EXA-4822 (trade names, manufactured by Dainippon Ink & Chemicals, Inc.), “RIKARESIN” (registered trademark) BEO-60E (trade name, manufactured by New Japan Chemical Co., Ltd.), and EP-40035 and EP-4000S (trade names, manufactured by ADEKA Corporation), which are available from the respective companies. The resin composition may contain two or more of these.

The content of the thermal crosslinking agent used in the present invention is preferably 0.5 parts by mass or more, more preferably 1 part by mass or more, still more preferably 10 parts by mass or more based on 100 parts by mass of the resin of the component (a), and is preferably 300 parts by mass or less, more preferably 200 parts by mass or less from the viewpoint of maintaining mechanical characteristics such as elongation.

The resin composition of the present invention may optionally contain a solvent. Preferable examples of the solvent include polar aprotic solvents such as N-methyl-2-pyrrolidone, γ-butyrolactone, N,N-dimethylformamide, N,N-dimethylacetamide, and dimethylsulfoxide, ethers such as tetrahydrofuran, dioxane, propylene glycol monomethyl ether, and propylene glycol monoethyl ether, ketones such as acetone, methyl ethyl ketone, and diisobutyl ketone, esters such as ethyl acetate, butyl acetate, isobutyl acetate, propyl acetate, propylene glycol monomethyl ether acetate, and 3-methyl-3-methoxybutyl acetate, alcohols such as ethyl lactate, methyl lactate, diacetone alcohol, and 3-methyl-3-methoxybutanol, and aromatic hydrocarbons such as toluene and xylene. The resin composition may contain two or more of these.

The content of the solvent is preferably 70 parts by mass or more, more preferably 100 parts by mass or more based on 100 parts by mass of the resin of the component (a) from the viewpoint of resin dissolution, and is preferably 1,800 parts by mass or less, more preferably 1,500 parts by mass or less from the viewpoint of obtaining an appropriate film thickness.

The resin composition of the present invention may optionally contain a thermal acid generator. When the resin composition contains a thermal acid generator, the resulting cured film has a high crosslinking rate, a high benzoxazole ring closure rate, and a high imide ring closure rate even when being fired at a temperature of 150 to 300° C. that is lower than usual.

The content of the thermal acid generator that is preferable for the purpose of exhibiting the above-mentioned effect is preferably 0.01 parts by mass or more, more preferably 0.1 parts by mass or more based on 100 parts by mass of the resin of the component (a), and is preferably 30 parts by mass or less, more preferably 15 parts by mass or less from the viewpoint of maintaining mechanical characteristics such as elongation.

The resin composition of the present invention may optionally contain a low-molecular compound having a phenolic hydroxyl group. When the resin composition contains a low-molecular compound having a phenolic hydroxyl group, the alkali solubility can be easily adjusted in patterning.

The content of the low-molecular compound having a phenolic hydroxyl group that is preferable for the purpose of exhibiting the above-mentioned effect is preferably 0.1 parts by mass or more, more preferably 1 part by mass or more based on 100 parts by mass of the resin of the component (a), and is preferably 30 parts by mass or less, more preferably 15 parts by mass or less from the viewpoint of maintaining mechanical characteristics such as elongation.

The resin composition of the present invention may optionally contain surfactants, esters such as ethyl lactate and propylene glycol monomethyl ether acetate, alcohols such as ethanol, ketones such as cyclohexanone and methyl isobutyl ketone, and ethers such as tetrahydrofuran and dioxane for the purpose of improving the wettability to the substrate.

A preferable content of these compounds used for the purpose of improving the wettability to the substrate is 0.001 parts by mass or more based on 100 parts by mass of the resin of the component (a), and is preferably 1,800 parts by mass or less, more preferably 1,500 parts by mass or less from the viewpoint of obtaining an appropriate film thickness.

The resin composition of the present invention may contain inorganic particles. Preferable specific examples thereof include silicon oxide, titanium oxide, barium titanate, alumina, and talc, but the inorganic particles are not limited thereto.

The primary particle size of these inorganic particles is preferably 100 nm or less, particularly preferably 60 nm or less from the viewpoint of maintaining the sensitivity.

As for the primary particle size of the inorganic particles, there is a calculation method of obtaining the primary particle size as a number average particle size from the specific surface area. The specific surface area is defined as the sum of surface areas of particles included in a unit mass of a powder. One method for measuring the specific surface area is a BET method, and the specific surface area can be measured using a specific surface area measuring apparatus (for example, HM model-1201 manufactured by Mountech Co., Ltd.).

Moreover, the resin composition may contain a silane coupling agent such as trimethoxyaminopropylsilane, trimethoxyepoxysilane, trimethoxyvinylsilane, or trimethoxythiolpropylsilane in order to improve the adhesion properties to the silicon substrate.

A preferable content of such a compound used for the purpose of improving the adhesion properties to the silicon substrate is 0.01 parts by mass or more based on 100 parts, by mass of the resin of the component (a), and is preferably 5 parts by mass or less from the viewpoint of maintaining mechanical characteristics such as elongation.

The resin composition of the present invention preferably has a viscosity of 2 to 5000 mPa·s. Adjusting the solid content concentration so that the resin composition may have a viscosity of 2 mPa√s or more makes it easy to achieve a desired film thickness. On the other hand, when the viscosity is 5000 mPa·s or less, it is easy to give a coating film with high uniformity. A resin composition having such a viscosity can be easily obtained, for example, by setting the solid content concentration to 5 to 60% by mass.

Then, a method of forming a resin pattern using a photosensitive resin composition obtained by imparting photosensitivity to the resin composition of the present invention will be described. An example of the method of imparting photosensitivity is a method using the quinone diazide compound (c).

The photosensitive resin composition of the present invention is applied to a substrate. The substrate may be a wafer made of silicon, ceramics, gallium arsenide or the like, or such a wafer having a metal thereon as an electrode or wiring, but the substrate is not limited thereto. Examples of the coating method include methods such as spin coating using a spinner, spray coating, and roll coating. The thickness of the coating film varies depending on the coating technique, solid content concentration and viscosity of the composition, and the like. Usually, the resin composition is applied so that the coating film obtained after the drying may have a thickness of 0.1 to 150 μm.

It is also possible to pretreat the substrate with the above-mentioned silane coupling agent in order to improve the adhesion properties between the substrate and the photosensitive resin composition. For example, the substrate is subjected to surface treatment with a solution prepared by dissolving 0.5 to 20% by mass of a silane coupling agent in a solvent such as isopropanol, ethanol, methanol, water, tetrahydrofuran, propylene glycol monomethyl ether acetate, propylene glycol monomethyl ether, ethyl lactate, or diethyl adipate by spin coating, immersion, spray coating, steam treatment or the like. In some cases, heat treatment is then performed at 50 to 300° C. to advance the reaction between the substrate and the silane coupling agent.

Then, the substrate to which the photosensitive resin composition is applied is dried to give a photosensitive resin composition coating film. The substrate is preferably dried with an oven, a hot plate, infrared rays or the like at temperature in the range of 50 to 150° C. for 1 minute to several hours.

Then, the photosensitive resin composition coating film is exposed to actinic rays through a mask having a desired pattern. Examples of the actinic rays used in exposure include ultraviolet rays, visible rays, electron beam, and X-ray. In the present invention, it is preferable to use i-line (365 nm), h-line (405 nm), or g-line (436 nm) of a mercury lamp.

In the exposure, for example, a half-tone mask may be used, or the exposure energy may be varied depending on the exposed position in the substrate by a method such as a method of performing exposure a plurality of times at different exposed positions, masks, and exposure energies. This makes it easy to form the level difference pattern described later.

In order to form a resin pattern, the resin is developed using a developer after the exposure. As the developer, it is preferable to use an aqueous solution of a compound having alkalinity, such as tetramethylammonium hydroxide, diethanolamine, diethylaminoethanol, sodium hydroxide, potassium hydroxide, sodium carbonate, potassium carbonate, triethylamine, diethylamine, methylamine, dimethylamine, dimethylaminoethyl acetate, dimethylaminoethanol, dimethylaminoethyl methacrylate, cyclohexylamine, ethylenediamine, or hexamethylenediamine. In some cases, to the alkali aqueous solution, polar solvents such as N-methyl-2-pyrrolidone, N,N-dimethylformamide, N,N-dimethylacetamide, dimethylsulfoxide, γ-butyrolactone, and dimethylacrylamide, alcohols such as methanol, ethanol, and isopropanol, esters such as ethyl lactate and propylene glycol monomethyl ether acetate, and ketones such as cyclopentanone, cyclohexanone, isobutyl ketone, and methyl isobutyl ketone may be added alone or in combination of several kinds. After the development, the resin pattern is preferably rinsed with water. In this process too, alcohols such as ethanol and isopropyl alcohol, and esters such as ethyl lactate and propylene glycol monomethyl ether acetate may be added to water for the rinsing.

In the development, one of the exposed portion and the unexposed portion may be entirely removed, or all or a part of the exposed portion and/or the unexposed portion may be left without being completely removed to form a level difference pattern. That is, when the resin composition is used as a positive photosensitive resin composition, all or a part of the exposed portion may be left without being removed, whereas when the resin composition is used as a negative photosensitive resin composition, all or a part of the unexposed portion may be left without being removed. The present invention works particularly well in formation of a relief pattern having a plurality of levels that is capable of suppressing surface roughness in a thin film portion having a thickness of 0.1 μm or more and 3.0 μm or less, and is therefore suitably used in forming such a level difference pattern.

In forming a level difference pattern, a control technique of stopping the development at the stage where the thin film portion comes to have a desired film thickness is important. In order to control the developing amount, the developing speed may be controlled by the exposure energy, the developing speed may be controlled by the type, concentration, and mixing ratio of developers, and the developing amount may be controlled by the developing time. A combination of these may also be used.

After the development, it is preferable to apply a temperature of 150 to 500° C. to the resin to advance the thermal crosslinking reaction, imide ring closure reaction, and oxazole ring closure reaction for curing the resin. With this operation, the heat resistance and chemical resistance of the resin pattern can be improved. The heat treatment is preferably performed for 5 minutes to 5 hours by selecting a temperature and raising the temperature in stages or selecting a certain temperature range and continuously raising the temperature. As an example, the heat treatment is performed at 150° C., 220° C., and 320° C. for 30 minutes each. Alternatively, there is also a method of linearly raising the temperature from room temperature to 400° C. over 2 hours.

In the case of forming a level difference pattern as a positive photosensitive resin composition, the resin composition is usable for a pattern as long as the rate of film thickness of the pattern left without being removed in the exposed portion to the film thickness of the unexposed portion after curing is within the range of 0.1% or more and 99% or less. However, the film thickness is preferably 1% or more, more preferably 3% or more, still more preferably 5% or more, particularly preferably 10% or more from the viewpoint of maintaining the insulation reliability. of the thin film portion, and is preferably 90% or less, more preferably 70% or less, still more preferably 50% or less, particularly preferably 40% or less from the viewpoint of difference in thickness from the unexposed portion.

The resin pattern formed from the positive photosensitive resin composition of the present invention can be suitably used in applications such as a passivation film of a semiconductor, a protective film for a semiconductor device, an interlayer insulating film for multilayer wiring for high-density packaging, and an insulation layer of an organic electroluminescent device.

### EXAMPLES

Hereinafter, the present invention will be described with reference to examples, but the present invention is not limited to these examples. First, the evaluation methods in each of the examples and comparative examples will be described. For the evaluation of a resin composition (hereinafter referred to as a varnish), a varnish which had been filtered with a filter having a pore size of 1 μm and made of polytetrafluoroethylene (manufactured by Sumitomo Electric Industries, Ltd.) in advance was used.

(1) Measurement of Film Thickness

The thickness of a resin coating film on the substrate was measured with an optical interference film thickness measuring apparatus (Lambda Ace VM-1030 manufactured by Dainippon Screen Mfg. Co., Ltd.). The film thickness was measured with the refractive index of a polyimide being set at 1.629.

(2) Measurement of Alkali Dissolution Rate

A resin was dissolved in γ-butyrolactone (hereinafter referred to as GBL) so that the resulting solution would have a solid content concentration of 35% by mass. The solution was applied to a 6-inch silicon wafer and prebaked on a hot plate at 120° C. for 4 minutes to form a prebaked film having a thickness of 10 μm±0.5 μm. The prebaked film was immersed in a 2.38% by mass aqueous tetramethylammonium hydroxide solution at 23±1° C. for 1 minute. The thickness of the dissolved portion of the film was calculated from the film thicknesses before and after immersion, and the thickness of the film dissolved per minute was defined as the alkali dissolution rate. When the resin film was completely dissolved within less than 1 minute, the time required for dissolution was measured, and the thickness of the film dissolved per minute was determined from the obtained time and the film thickness before immersion. The result was defined as the alkali dissolution rate.

(3) Weight Average Molecular Weight

Using a gel permeation chromatography (GPC) apparatus (Waters 2690-996 manufactured by Nihon Waters K.K.) and N-methyl-2-pyrrolidone (hereinafter referred to as NMP) as a developing solvent, the weight average molecular weight (Mw) was measured and calculated in terms of polystyrene.

(4) Imide Ring Closure Rate (R_{IM} (% ))

An alkali-soluble polyimide or a precursor resin thereof was dissolved in GBL so that the resulting solution would have a solid content concentration of 35% by mass, and the solution was applied to a 4-inch silicon wafer by spin coating with a spinner (1H-DX manufactured by Mikasa Co., Ltd.). Then, the solution was baked on a hot plate (D-SPIN manufactured by Dainippon Screen Mfg. Co., Ltd.) at 120° C. for 3 minutes to produce a prebaked film having a thickness of 4 to 5 μm. The wafer with a resin film was divided into two halves, and one was fired under a nitrogen stream (oxygen concentration: 20 ppm or less) at 140° C. for 30 minutes using a clean oven (CLH-21CD-S manufactured by Koyo Thermo Systems Co., Ltd.). Then, the temperature was raised and the wafer was fired at 320° C. for 1 hour. The transmitted infrared absorption spectra of the resin film before and after the firing were measured with an infrared spectrophotometer (FT-720 manufactured by HORIBA, Ltd.). The presence of absorption peaks (around 1780 cm⁻¹ and around 1377 cm⁻¹) of the imide structure attributable to a polyimide was confirmed, and the peak intensities around 1377 cm⁻¹ (before firing: X, after firing: Y) were obtained. The peak intensity ratio between them was calculated, and the content of imide groups in the polymer before heat treatment, that is, the imide ring closure rate was determined (R_{IM}=X/Y×100(%)).

(5) Level Difference Patternability

A varnish was applied to an 8-inch silicon wafer using a coating and developing apparatus (ACT-8 manufactured by Tokyo Electron Limited) by spin coating so that the film obtained after prebaking at 120° C. for 3 minutes would have a desired thickness. A mask with an incised pattern was set on an exposure machine i-line, stepper (NSR-2005i9C manufactured by Nikon Corporation), and the prebaked substrate was set on the exposure machine and exposed to light at an exposure energy of 100 to 900 mJ/cm² in 10 mJ/cm² steps. After the exposure, the substrate was subjected to paddle (the time was appropriately adjusted) development twice using ACT-8 as the developing apparatus and using a 2.38% by mass aqueous tetramethylammonium hydroxide (hereinafter referred to as TMAH) solution (ELM-D manufactured by MITSUBISHI GAS CHEMICAL COMPANY, INC.) by a paddle method for a discharge time of the developer of 5 seconds, rinsed with pure water, and then dried by shaking off of the moisture. The silicon wafer with a resin film after the development was fired under a nitrogen stream (oxygen concentration: 20 ppm or less) at 140° C. for 30 minutes using a clean oven CLH-21CD-S. Then, the temperature was raised and the wafer was fired at a predetermined temperature for 1 hour. When the temperature reached 50° C. or lower, the silicon wafer was taken out, and the film thickness of the unexposed portion was measured. A standard condition of the film thickness of the unexposed portion was defined as 5 μm, and the silicon wafer was processed so that the unexposed portion would have the thickness of 5 μm by adjusting the film thickness after the prebaking and the paddle time in the development. The level difference patternability was also evaluated as appropriate under the conditions where the film thickness of the unexposed portion was 3 μm and/or 7 μm. The exposure energies at which the film thickness of the exposed portion after curing was 2.0±0.2 μm and 1.0±0.2 μm, and the minimum exposure energy at which the film thickness was 0 μm (the exposed portion was completely removed) were determined. Moreover, using the optical microscope of VM-1030, surface conditions of line patterns having a width of 50 μm at the positions where the film thicknesses were 2.0±0.2 μm and 1.0±0.2 μm were observed. Those having no roughness in the appearance observation were evaluated as excellent (3), those having slight roughness with light haze were evaluated as good (2), and those having roughness on the surface were evaluated as poor (1).

(6) Insulation Properties

In the evaluation of level difference patternability in (5), the process was performed in the same manner as in (5) except that a boron-doped silicon wafer having a resistance value of 0.1 Ω·cm or less was used, the wafer was exposed to light without any mask set on the i-line stepper, and the film thickness of the unexposed portion after the curing was adjusted to 5.0±0.2 μm. The film thicknesses of the exposed portion were measured at positions where the film thicknesses after curing were 2.0±0.2 μm, and 1.0±0.2 μm. Using a withstand voltage/insulating-resistance tester (TOS9201 manufactured by KIKUSUI ELECTRONICS CORP.), a probe was brought into contact with the positions where the film thicknesses were 2.0±0.2 μm and 1.0±0.2 μm, and the pressure was raised at a pressure rise rate of 0.1 kV/4 sec in the DCW. The voltage at the time when breakdown occurred was measured, and the breakdown voltage per unit film thickness was obtained. When the breakdown voltage per a film thickness of 1 mm was less than 200 kV, the film was evaluated as having insufficient insulation properties (1), and when the breakdown voltage was 200 kV or more, the film was evaluated as having satisfactory insulation properties (2).

### Synthesis Example 1

### Synthesis of Diamine Compound (HA)

In 900 mL of acetone and 156.8 g (2.7 mol) of propylene oxide, 164.8 g (0.45 mol) of 2,2-bis (3-amino-4-hydroxyphenyl)hexafluoropropane (hereinafter referred to as BAHF) was dissolved, and the solution was cooled to -15° C. A solution of 183.7 g (0.99 mol) of 3-nitrobenzoyl chloride in 900 mL of acetone was added dropwise thereto. After completion of the dropwise addition, the mixture was reacted at −15° C. for 4 hours, and then returned to room temperature. The deposited white solid was separated by filtration, and vacuum dried at 50° C.

In a 3-L stainless steel autoclave, 270 g of the solid was placed and dispersed in 2400 mL of methyl cellosolve, and 5 g of 5% palladium-carbon was added thereto. Hydrogen was introduced into the mixture by a balloon, and a reduction reaction was performed at room temperature. After 2 hours, it was confirmed that the balloon would not deflate anymore, and the reaction was completed. After completion of the reaction, the palladium compound as a catalyst was removed by filtration, and the mixture was concentrated with a rotary evaporator to give a diamine compound represented by the following formula (hereinafter referred to as HA).

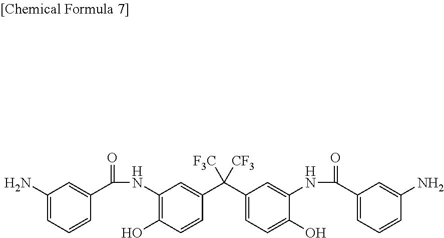 [SMILES: Nc1cccc(C(=O)Nc2cc(C(c3ccc(O)c(NC(=O)c4cccc(N)c4)c3)(C(F)(F)F)C(F)(F)F)ccc2O)c1]

### Synthesis Example 2

### Synthesis of Alkali-Soluble Polyimide Resin (A-1)

Under a dry nitrogen stream, 87.90 g (0.24 mol) of BAHF, 3.73 g (0.015 mol) of 1,3-bis(3-aminopropyl)tetramethyldisiloxane, and 9.82 g (0.09 mol) of 4-aminophenol (manufactured by Tokyo Chemical Industry Co., Ltd.) as an end-capping agent were dissolved in 730 g of NMP. To the solution, 93.07 g (0.3 mol) of bis(3,4-dicarboxyphenyl)ether dianhydride (hereinafter referred to as ODPA) was added together with 20 g of NMP, and the mixture was reacted at 20° C. for 1 hour and then at 50° C. for 4 hours. Then, 20 g of xylene was added to the mixture, and the mixture was stirred at 150° C. for 5 hours while water was azeotropically distilled together with xylene. After completion of the stirring, the solution was cooled to room temperature, and then the solution was poured into 5 L of water to give a precipitate. The precipitate was collected by filtration, washed three times with water, and then dried in a vacuum dryer at 80° C. for 20 hours to give a powder of an alkali-soluble polyimide resin (A-1).

### Synthesis Example 3

### Synthesis of Alkali-Soluble Polyimide Resin (A-2)

A polymerization reaction was performed in the same manner as in Synthesis Example 2 except that the diamine was changed to 71.42 g (0.195 mol) of BAHF, 3.73 g (0.015 mol) of 1,3-bis(3-aminopropyl)tetramethyldisiloxane, and 27.20 g (0.045 mol) of HA to give a powder of an alkali-soluble polyimide resin (A-2).

### Synthesis Example 4

### Synthesis of Alkali-Soluble Polyimide Resin (A-3)

A polymerization reaction was performed in the same manner as in Synthesis Example 2 except that the amount of diamine added was changed to 82.41 g (0.225 mol) of BAHF and 3.73 g (0.015 mol) of 1,3-bis (3-aminopropyl)tetramethyldisiloxane, and the amount of end-capping agent added was changed to 13.10 g (0.12 mol) of 4-aminophenol to give a powder of an alkali-soluble polyimide resin (A-3).

### Synthesis Example 5

### Synthesis of Alkali-Soluble Polyimide-Benzoxazole Precursor Resin (A-4)

Under a dry nitrogen stream, 62.04 g (0.2 mol) of ODPA was dissolved in 630 g of NMP. To the mixture, 106.39 g (0.176 mol) of HA and 1.99 g (0.008 mol) of 1,3-bis (3-aminopropyl) tetramethyldisiloxane were added together with 20 g of NMP, and the mixture was reacted at 20° C. for 1 hour and then at 50° C. for 2 hours. Then, 3.49 g (0.032 mol) of 4-aminophenol as an end-capping agent was added together with 10 g of NMP, and the mixture was reacted at 50° C. for 2 hours. Then, a solution prepared by diluting 42.90 g (0.36 mol) of N,N-dimethylformamide dimethyl acetal with 80 g of NMP was added dropwise over 10 minutes. After the dropwise addition, the mixture was stirred at 50° C. for 3 hours. After completion of the stirring, the solution was cooled to room temperature, and then the solution was poured into 5 L of water to give a precipitate. The precipitate was collected by filtration, washed three times with water, and then dried in a vacuum dryer at 80° C. for 20 hours to give a powder of an alkali-soluble polyimide-benzoxazole precursor resin (A-4).

### Synthesis Example 6

### Synthesis of Alkali-Soluble Polyhydroxystyrene Resin (B-1)

To a mixed solution of 2400 g of tetrahydrofuran and 2.56 g (0.04 mol) of sec-butyllithium as an initiator, 95.18 g (0.54 mol) of p-t-butoxystyrene and 6.25 g (0.06 mol) of styrene were added. The resulting mixture was polymerized with stirring for 3 hours, and a polymerization termination reaction was performed by adding 12.82 g (0.4 mol) of methanol. Then, in order to purify the polymer, the reaction mixture was poured into 3 L of methanol, the precipitated polymer was dried and further dissolved in 1.6 L of acetone, 2 g of concentrated hydrochloric acid was added to the solution at 60° C. and the mixture was stirred for 7 hours, and then the mixture was poured into water to precipitate the polymer. The p-t-butoxystyrene was deprotected and converted into hydroxystyrene, washed three times with water, and then dried in a vacuum dryer at 50° C. for 24 hours to give an alkali-soluble polyhydroxystyrene resin (B-1).

### Synthesis Example 7

### Synthesis of Alkali-Soluble Novolak Resin (B-2)

Under a dry nitrogen stream, 32.44 g (0.3 mol) of m-cresol, 75.70 g (0.7 mol) of p-cresol, 75.5 g of a 37% by mass aqueous formaldehyde solution (0.93 mol of formaldehyde), 0.63 g (0.005 mol) of oxalic acid dihydrate, and 260 g of methyl isobutyl ketone were charged, and then the mixture was immersed in an oil bath and subjected to a polycondensation reaction for 4 hours with the reaction liquid being refluxed. Then, the temperature of the oil bath was raised over 3 hours, after which the pressure in the flask was reduced to 40 to 67 hPa, and the volatile matter was removed. The dissolved resin was cooled to room temperature to give a polymer solid of an alkali-soluble novolak resin (B-2).

### Synthesis Example 8

### Synthesis of Alkali-Soluble Novolak Resin (B-3)

A polycondensation reaction was performed in the same manner as in Synthesis Example 7 except that the phenols were changed to 64.88 g (0.6 mol) of m-cresol, 32.44,g (0.3 mol) of p-cresol, and 12.22 g (0.1 mol) of 2,5-dimethylphenol to give a polymer solid of an alkali-soluble novolak resin (B-3).

### Synthesis Example 9

### Synthesis of Alkali-Soluble Novolak Resin (B-4)

A polycondensation reaction was performed in the same manner as in Synthesis Example 7 except that the phenols were changed to 86.51 g (0.8 mol) of m-cresol and 21.63 g (0.2 mol) of p-cresol to give a polymer solid of an alkali-soluble novolak resin (B-4).

### Synthesis Example 10

### Synthesis of Alkali-Soluble Novolak Resin (B-5)

A polycondensation reaction was performed in the same manner as in Synthesis Example 7 except that the phenols were changed to 75.70 g (0.7 mol) of m-cresol, 21.63 g (0.2 mol) of p-cresol, and 12.22 g (0.1 mol) of 2,5-dimethylphenol to give a polymer solid of an alkali-soluble novolak resin (B-5).

### Synthesis Example 11

### Synthesis of Alkali-Soluble Polyhydroxystyrene Resin (B-6)

A polymerization reaction was performed in the same manner as in Synthesis Example 6 except that the amounts of styrenes added were changed to 63.45 g (0.36 mol) of p-t-butoxystyrene and 25.00 g (0.24 mol) of styrene to give an alkali-soluble polyhydroxystyrene resin (B-6).

### Synthesis Example 12

### Synthesis of Quinone Diazide Compound (C-1)

Under a dry nitrogen stream, 42.45 g (0.1 mol) of TrisP-PA (trade name, manufactured by Honshu Chemical Industry Co., Ltd.) and 75.23 g (0.28 mol) of 5-naphthoquinonediazide sulfonyl chloride (NAC-5 manufactured by Toyo Gosei Co., Ltd.) were dissolved in 1000 g of 1,4-dioxane. While the reaction vessel was cooled with ice, a liquid mixture of 150 g of 1,4-dioxane and 30.36 g (0.3 mol) of triethylamine was added dropwise so that the inside of the system would not reach 35° C. or higher. After the dropwise addition, the mixture was stirred at 30° C. for 2 hours. The triethylamine salt was filtered, and the filtrate was poured into 7 L of pure water to give a precipitate. The precipitate was collected by filtration, and further washed with 2 L of 1% by mass hydrochloric acid. Then, the precipitate was further washed twice with 5 L of pure water. The precipitate was dried in a vacuum dryer at 50° C. for 24 hours to give a quinone diazide compound (C-1) represented by the following formula in which 2.8 on average of Qs were esterified into 5-naphthoquinonediazide sulfonic acid ester.

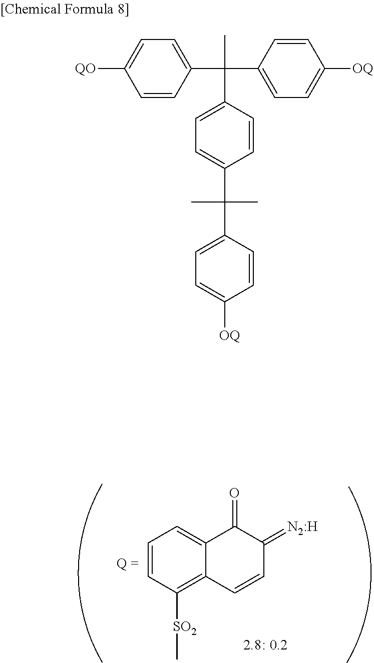

The thermal crosslinking agent HMOM-TPHAP (trade name, manufactured by Honshu Chemical Industry Co., Ltd.) (D-1) used in the examples is shown below.

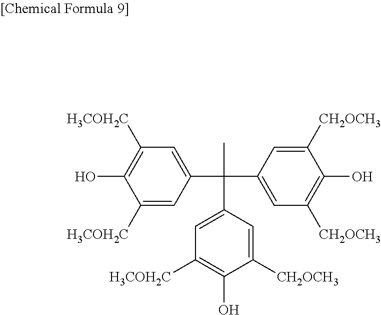

As for the alkali-soluble resins (A-1 to A-4 and B-1 to B-6) obtained in Synthesis Examples 2 to 11, Table 1 shows the alkali dissolution rate, the weight average molecular weight, the imide ring closure rate (R_{IM} (%)) for the resins of the component (a) (A-1 to A-4), and the rate of structural unit represented by the formula (2) or (3) in the total of all structural units, which is calculated from the amount of each resin added, for the resins of the component (b) (B-1 to B-6).

TABLE 1

| | Alkali | Weight average | | |
|---|---|---|---|---|
| | dissolution | molecular | Imide ring | Rate of structural |
| | rate | weight | closure rate | unit of formula (2) or |
| Resin | (nm/min) | M_{W} | R_{IM} (%) | (3) (%) |
| A-1 | 12643 | 22400 | 100 | — |
| A-2 | 3724 | 23000 | 100 | — |
| A-3 | 23093 | 19300 | 99 | — |
| A-4 | 1988 | 24600 | 13 | — |
| B-1 | 26137 | 5200 | — | 90 |
| B-2 | 20728 | 3500 | — | 100 |
| B-3 | 12173 | 4600 | — | 90 |
| B-4 | 7062 | 8100 | — | 100 |
| B-5 | 4317 | 13700 | — | 90 |
| B-6 | 3132 | 4100 | — | 60 |

[Production of Varnish]

The components according to the formulation shown in Table 2 were charged into a polypropylene vial having a volume of 32 mL, and the components were mixed under the conditions of stirring for 10 minutes and defoaming for 1 minute using a stirring defoaming apparatus (ARE-310 manufactured by THINKY CORPORATION). The mixture was filtered by the above-mentioned method to remove minute foreign matters, and thereby varnishes (W-1 to W-26) were produced. In Table 2, “GBL” represents γ-butyrolactone.

TABLE 2

| | | | | Thermal | | Alkali |
|---|---|---|---|---|---|---|
| | | | (c) Quinone | cross- | | dissolution |
| | Resin | Resin | diazide | linking | | rate ratio |
| Varnish | of (a) | of (b) | compound | agent | Solvent | Rb/Ra |
| W-1 | A-1 | B-2 | C-1 | — | GBL | 1.64 |
| | 6.3 g | 2.7 g | 1.35 g | | 15.5 g | |
| W-2 | A-1 | B-2 | C-1 | — | GBL | 1.64 |
| | 3.6 g | 5.4 g | 1.35 g | | 15.5 g | |
| W-3 | A-1 | B-3 | C-1 | — | GBL | 0.96 |
| | 6.3 g | 2.7 g | 1.35 g | | 15.5 g | |
| W-4 | A-1 | B-3 | C-1 | — | GBL | 0.96 |
| | 3.6 g | 5.4 g | 1.35 g | | 15.5 g | |
| W-5 | A-1 | B-4 | C-1 | — | GBL | 0.56 |
| | 6.3 g | 2.7 g | 1.35 g | | 15.5 g | |
| W-6 | A-1 | B-2 | C-1 | D-1 | GBL | 1.64 |
| | 5.6 g | 2.4 g | 1.2 g | 0.8 g | 15 g | |
| W-7 | A-1 | B-3 | C-1 | D-1 | GBL | 0.96 |
| | 5.6 g | 2.4 g | 1.2 g | 0.8 g | 15 g | |
| W-8 | A-1 | B-4 | C-1 | D-1 | GBL | 0.56 |
| | 5.6 g | 2.4 g | 1.2 g | 0.8 g | 15 g | |
| W-9 | A-2 | B-4 | C-1 | — | GBL | 1.90 |
| | 6.3 g | 2.7 g | 1.35 g | | 15.5 g | |
| W-10 | A-2 | B-5 | C-1 | — | GBL | 1.16 |
| | 6.3 g | 2.7 g | 1.35 g | | 15.5 g | |
| W-11 | A-2 | B-6 | C-1 | — | GBL | 0.84 |
| | 6.3 g | 2.7 g | 1.35 g | | 15.5 g | |
| W-12 | A-3 | B-1 | C-1 | — | GBL | 1.13 |
| | 6.3 g | 2.7 g | 1.35 g | | 15.5 g | |
| W-13 | A-3 | B-2 | C-1 | — | GBL | 0.90 |
| | 6.3 g | 2.7 g | 1.35 g | | 15.5 g | |
| W-14 | A-3 | B-3 | C-1 | — | GBL | 0.53 |
| | 6.3 g | 2.7 g | 1.35 g | | 15.5 g | |
| W-15 | A-4 | B-6 | C-1 | — | GBL | 1.58 |
| | 6.3 g | 2.7 g | 1.35 g | | 15.5 g | |
| W-16 | A-1 | B-1 | C-1 | — | GBL | 2.07 |
| | 6.3 g | 2.7 g | 1.35 g | | 15.5 g | |
| W-17 | A-1 | B-1 | C-1 | — | GBL | 2.07 |
| | 3.6 g | 5.4 g | 1.35 g | | 15.5 g | |
| W-18 | A-1 | B-5 | C-1 | — | GBL | 0.34 |
| | 6.3 g | 2.7 g | 1.35 g | | 15.5 g | |
| W-19 | A-1 | B-1 | C-1 | D-1 | GBL | 2.07 |
| | 5.6 g | 2.4 g | 1.2 g | 0.8 g | 15 g | |
| W-20 | A-1 | B-5 | C-1 | D-1 | GBL | 0.34 |
| | 5.6 g | 2.4 g | 1.2 g | 0.8 g | 15 g | |
| W-21 | A-2 | B-1 | C-1 | — | GBL | 7.02 |
| | 6.3 g | 2.7 g | 1.35 g | | 15.5 g | |
| W-22 | A-2 | B-2 | C-1 | — | GBL | 5.57 |
| | 6.3 g | 2.7 g | 1.35 g | | 15.5 g | |
| W-23 | A-2 | B-3 | C-1 | — | GBL | 3.27 |
| | 6.3 g | 2.7 g | 1.35 g | | 15.5 g | |
| W-24 | A-3 | B-4 | C-1 | — | GBL | 0.31 |
| | 6.3 g | 2.7 g | 1.35 g | | 15.5 g | |
| W-25 | A-4 | B-5 | C-1 | — | GBL | 2.17 |
| | 6.3 g | 2.7 g | 1.35 g | | 15.5 g | |
| W-26 | A-4 | — | C-1 | — | GBL | — |
| | 9.0 g | | 1.35 g | | 15.5 g | |

### Examples 1 to 15 and Comparative Examples 1 to 11

Using the produced varnishes, the level difference patternability was evaluated by the above-mentioned method. The results are shown in Tables 3 to 5. All the varnishes were capable of level difference pattern formation by the adjustment of the processing conditions. In all of Examples 1 to 15, the surface condition was good at the positions where the film thickness after the exposure, development, and curing was 1.0±0.2 μm. On the other hand, in Comparative Examples 1 to 10, except for the one evaluated under the conditions where the film thickness of the unexposed portion after curing was 3 μm, roughness was observed on the surface at the positions where the film thickness after the exposure, development, and curing was 1.0±0.2 μm. In Comparative Example 11 in which the resin of the component (b) was not used, it was necessary to increase the exposure energy as compared with Example 3 in which the alkali dissolution rate of the resin component was close to that in Comparative Example 11. Moreover, the film in the unexposed portion greatly decreased in the development, and in a fine pattern having a width of 6 μm or less, the pattern of the unexposed portion adjacent to the exposed portion that was completely dissolved and removed was also dissolved and removed together, and the film had problems in sensitivity and patternability.

TABLE 3

| | | | | | Film thickness | Film thickness | | | | | | |
|---|---|---|---|---|---|---|---|---|---|---|---|---|
| | | | | | of unexposed | rate to | | | | | | |
| | | Film thickness | Paddle time in | Firing | portion after | unexposed portion | | Exposure energy | | | Surface | |
| | | after prebaking | development | temperature | curing | (%) | | (mJ/cm²) | | | condition | |
| | Varnish | (μm) | (sec/procedure) | (° C.) | (μm) | 2 μm | 1 μm | 2 μm | 1 μm | 0 μm | 2 μm | 1 μm |
| Example 1 | W-1 | 8.4 | 35 | 220 | 6.9 | 30 | 16 | 240 | 280 | 310 | 3 | 2 |
| | | 6.2 | 25 | 220 | 5.2 | 39 | 18 | 220 | 260 | 290 | 3 | 2 |
| | | 3.8 | 20 | 220 | 3.0 | 60 | 32 | 150 | 170 | 190 | 3 | 3 |
| Example 2 | W-2 | 8.6 | 35 | 220 | 7.1 | 30 | 14 | 220 | 260 | 290 | 3 | 2 |
| | | 5.9 | 25 | 220 | 4.8 | 39 | 17 | 200 | 240 | 260 | 3 | 2 |
| | | 3.7 | 20 | 220 | 2.9 | 67 | 39 | 130 | 150 | 170 | 3 | 3 |
| Example 3 | W-3 | 8.2 | 40 | 220 | 6.8 | 28 | 12 | 270 | 320 | 350 | 3 | 3 |
| | | 6.0 | 30 | 220 | 5.0 | 37 | 21 | 260 | 300 | 340 | 3 | 3 |
| | | 3.8 | 25 | 220 | 3.1 | 71 | 26 | 180 | 200 | 220 | 3 | 3 |
| Example 4 | W-4 | 8.2 | 40 | 220 | 6.9 | 30 | 12 | 260 | 300 | 320 | 3 | 3 |
| | | 5.9 | 30 | 220 | 4.9 | 45 | 18 | 260 | 300 | 330 | 3 | 3 |
| | | 3.8 | 25 | 220 | 3.1 | 64 | 36 | 170 | 190 | 220 | 3 | 3 |
| Example 5 | W-5 | 8.3 | 40 | 220 | 7.0 | 29 | 15 | 310 | 360 | 390 | 3 | 2 |
| | | 5.9 | 30 | 220 | 5.0 | 37 | 22 | 290 | 310 | 370 | 3 | 2 |
| | | 3.6 | 25 | 220 | 3.0 | 69 | 28 | 200 | 230 | 250 | 3 | 3 |

TABLE 4

| | | | | | Film thickness | Film thickness | | | | | | |
|---|---|---|---|---|---|---|---|---|---|---|---|---|
| | | | | | of unexposed | rate to | | | | | | |
| | | Film thickness | Paddle time in | Firing | portion after | unexposed portion | | Exposure energy | | | Surface | |
| | | after prebaking | development | temperature | curing | (%) | | (mJ/cm²) | | | condition | |
| | Varnish | (μm) | (sec/procedure) | (° C.) | (μm) | 2 μm | 1 μm | 2 μm | 1 μm | 0 μm | 2 μm | 1 μm |
| Example 6 | W-6 | 8.1 | 15 | 220 | 6.9 | 27 | 17 | 190 | 220 | 260 | 3 | 2 |
| | | 6.2 | 10 | 220 | 5.2 | 41 | 17 | 160 | 190 | 220 | 3 | 2 |
| Example 7 | W-7 | 8.2 | 20 | 220 | 7.0 | 30 | 16 | 240 | 290 | 330 | 3 | 3 |
| | | 5.8 | 15 | 220 | 4.9 | 38 | 24 | 230 | 270 | 320 | 3 | 3 |
| Example 8 | W-8 | 8.3 | 20 | 220 | 7.1 | 26 | 15 | 290 | 330 | 350 | 3 | 2 |
| | | 6.1 | 15 | 220 | 5.2 | 42 | 20 | 260 | 290 | 320 | 3 | 3 |
| Example 9 | W-9 | 5.8 | 40 | 220 | 4.9 | 44 | 21 | 420 | 510 | 570 | 2 | 2 |
| Example 10 | W-10 | 5.9 | 45 | 220 | 5.0 | 36 | 21 | 460 | 540 | 610 | 3 | 2 |
| Example 11 | W-11 | 5.7 | 45 | 220 | 4.9 | 45 | 21 | 510 | 590 | 640 | 3 | 3 |
| Example 12 | W-12 | 6.0 | 15 | 220 | 4.9 | 43 | 19 | 160 | 210 | 250 | 3 | 2 |
| Example 13 | W-13 | 6.0 | 15 | 220 | 4.9 | 43 | 21 | 190 | 240 | 270 | 3 | 3 |
| Example 14 | W-14 | 6.2 | 15 | 220 | 5.2 | 40 | 22 | 210 | 260 | 290 | 3 | 2 |
| Example 15 | W-15 | 6.4 | 60 | 320 | 5.0 | 43 | 21 | 560 | 700 | 810 | 2 | 2 |

TABLE 5

| | | | | | Film thickness | Film thickness | | | | | | |
|---|---|---|---|---|---|---|---|---|---|---|---|---|
| | | | | | of unexposed | rate to | | | | | | |
| | | Film thickness | Paddle time in | Firing | portion after | unexposed portion | | Exposure energy | | | Surface | |
| | | after prebaking | development | temperature | curing | (%) | | (mJ/cm²) | | | condition | |
| | Varnish | (μm) | (sec/procedure) | (° C.) | (μm) | 2 μm | 1 μm | 2 μm | 1 μm | 0 μm | 2 μm | 1 μm |
| Comparative | W-16 | 8.6 | 30 | 220 | 7.1 | 29 | 17 | 220 | 250 | 280 | 2 | 1 |
| Example 1 | | 5.9 | 20 | 220 | 4.8 | 38 | 20 | 200 | 240 | 270 | 3 | 1 |
| | | 3.6 | 15 | 220 | 2.9 | 73 | 30 | 140 | 160 | 190 | 3 | 2 |
| Comparative | W-17 | 8.2 | 20 | 220 | 6.9 | 28 | 15 | 190 | 220 | 240 | 2 | 1 |
| Example 2 | | 6.0 | 15 | 220 | 5.0 | 36 | 22 | 160 | 180 | 220 | 3 | 1 |
| Comparative | W-18 | 8.2 | 50 | 220 | 7.0 | 29 | 13 | 350 | 390 | 430 | 1 | 1 |
| Example 3 | | 5.8 | 40 | 220 | 4.9 | 40 | 22 | 310 | 350 | 390 | 1 | 1 |
| Comparative | W-19 | 6.0 | 10 | 220 | 4.9 | 40 | 22 | 170 | 200 | 230 | 3 | 1 |
| Example 4 | | | | | | | | | | | | |
| Comparative | W-20 | 6.0 | 15 | 220 | 5.2 | 41 | 22 | 310 | 340 | 380 | 1 | 1 |
| Example 5 | | | | | | | | | | | | |
| Comparative | W-21 | 6.1 | 35 | 220 | 4.9 | 42 | 18 | 300 | 360 | 410 | 1 | 1 |
| Example 6 | | | | | | | | | | | | |
| Comparative | W-22 | 6.0 | 35 | 220 | 4.9 | 44 | 20 | 340 | 400 | 470 | 1 | 1 |
| Example 7 | | | | | | | | | | | | |
| Comparative | W-23 | 5.9 | 35 | 220 | 5.0 | 37 | 17 | 390 | 460 | 520 | 1 | 1 |
| Example 8 | | | | | | | | | | | | |
| Comparative | W-24 | 6.0 | 20 | 220 | 4.9 | 43 | 21 | 240 | 270 | 300 | 1 | 1 |
| Example 9 | | | | | | | | | | | | |
| Comparative | W-25 | 6.5 | 60 | 320 | 5.0 | 43 | 18 | 510 | 620 | 750 | 2 | 1 |
| Example 10 | | | | | | | | | | | | |
| Comparative | W-26 | 7.5 | 40 | 320 | 5.0 | 39 | 20 | 400 | 460 | 520 | 3 | 2 |
| Example 11 | | | | | | | | | | | | |

### Examples 16 to 25 and Comparative Examples 12 to 17

The insulation properties were evaluated by the above-mentioned method using the varnishes W-1, W-3, W-5 to W-8, W-10 to W-12, W-15, W-17 to W-19, and W-23 to W-25. The results are shown in Table 6. In all of the comparative examples, the films had insufficient insulation properties at the positions where the film thickness after the exposure, development, and curing was 1.0±0.2 μm.

TABLE 6

| | | | Position of 2 μm | | Position of 1 μm | |
|---|---|---|---|---|---|---|
| | | Firing | after curing | | after curing | |
| | | temperature | Breakdown voltage | | Breakdown voltage | |
| | Varnish | (° C.) | (kV/mm) | Judgment | (kV/mm) | Judgment |
| Example 16 | W-1 | 220 | 333 | 2 | 379 | 2 |
| Example 17 | W-3 | 220 | 410 | 2 | 391 | 2 |
| Example 18 | W-5 | 220 | 450 | 2 | 465 | 2 |
| Example 19 | W-6 | 220 | 408 | 2 | 424 | 2 |
| Example 20 | W-7 | 220 | 369 | 2 | 398 | 2 |
| Example 21 | W-8 | 220 | 391 | 2 | 433 | 2 |
| Example 22 | W-10 | 220 | 444 | 2 | 465 | 2 |
| Example 23 | W-11 | 220 | 371 | 2 | 330 | 2 |
| Example 24 | W-12 | 220 | 307 | 2 | 256 | 2 |
| Example 25 | W-15 | 320 | 356 | 2 | 389 | 2 |
| Comparative | W-17 | 220 | 307 | 2 | 149 | 1 |
| Example 12 | | | | | | |
| Comparative | W-18 | 220 | 291 | 2 | 86 | 1 |
| Example 13 | | | | | | |
| Comparative | W-19 | 220 | 333 | 2 | 111 | 1 |
| Example 14 | | | | | | |
| Comparative | W-23 | 220 | 177 | 1 | 80 | 1 |
| Example 15 | | | | | | |
| Comparative | W-24 | 220 | 159 | 1 | 68 | 1 |
| Example 16 | | | | | | |
| Comparative | W-25 | 320 | 311 | 2 | 135 | 1 |
| Example 17 | | | | | | |

1. A resin composition comprising:
(a) at least one resin selected from an alkali-soluble polyimide, an alkali-soluble polybenzoxazole, an alkali-soluble polyamide-imide, precursors thereof, and copolymers thereof; and
(b) an alkali-soluble phenol resin,
wherein a ratio (R_{b}/Rₐ) between an alkali dissolution rate (Rₐ) of the resin (a) and an alkali dissolution rate (R_{b}) of the resin (b) satisfies a relationship of 0.5≤R_{b}/Rₐ≤2.0.

2. The resin composition according to claim 1, wherein the ratio (R_{b}/Rₐ) between the alkali dissolution rate (Rₐ) of the resin (a) and the alkali dissolution rate (R_{b}) of the resin (b) satisfies a relationship of 0.8≤R_{b}/Rₐ<1.0.

3. The resin composition according to claim 1, further comprising (c) a quinone diazide compound and having photosensitivity.

4. The resin composition according to claim 1, wherein the resin (b) has a weight average molecular weight of 1,000 or more and 30,000 or less.

5. The resin composition according to claim 1, wherein the alkali dissolution rate (Rₐ) of the resin (a) is 1,000 nm/min or more and 20,000 nm/min or less.

6. The resin composition according to claim 1, wherein the resin (a) contains a structural unit represented by the general formula (1) in an amount of 50% or more and 100% or less of a total of all structural units: 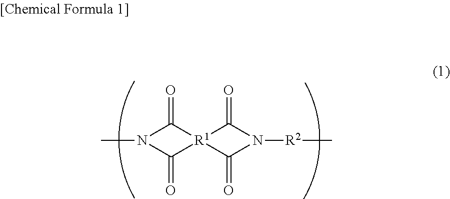
wherein R¹ represents a tetravalent organic group, and R² represents a divalent organic group.

7. The resin composition according to claim 1, wherein the resin (a) has 2.0 mol/kg or more and 3.5 mol/kg or less of a phenolic hydroxyl group.

8. The resin composition according to claim 1, wherein the resin (a) has a weight average molecular weight of 18,000 or more and 30,000 or less.

9. The resin composition according to claim 1, wherein the resin (b) contains at least one of a structural unit represented by the formula (2) and a structural unit represented by the formula (3) in an amount of 50% or more and 95% or less of a total of all structural units:

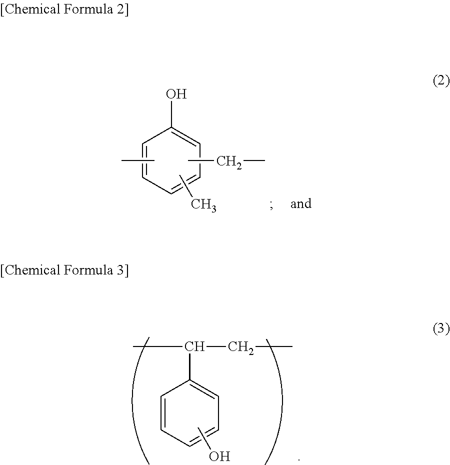

10. A cured relief pattern that is a cured product of the resin composition according to claim 1.

11. The cured relief pattern according to claim 10, wherein at least a part of an exposed portion has a film thickness that is 5% or more and 50% or less of a film thickness of an unexposed portion.

12. The cured relief pattern according to claim 10, having a breakdown voltage per a film thickness of 1 mm of 200 kV or more at a position where the cured relief pattern has a film thickness of 0.1 μm or more and 3.0 μm or less.

13. A method for manufacturing a cured relief pattern, the method comprising the steps of:
applying the resin composition according to claim 1 to a substrate and drying the resin composition to form a resin film;
exposing the resin film to light through a mask;
developing the exposed resin film to form a relief pattern; and
heating and curing the developed relief pattern,
wherein the step of heating and curing the developed relief pattern includes a step of forming a cured relief pattern in which at least a part of an exposed portion has a film thickness that is 5% or more and 50% or less of a film thickness of an unexposed portion.

14. An interlayer insulating film or a semiconductor protective film, comprising the cured relief pattern according to claim 10.

15. A method for manufacturing an interlayer insulating film or a semiconductor protective film using a cured relief pattern manufactured by the method according to claim 13.

16. A semiconductor electronic component or a semiconductor equipment, comprising the cured relief pattern according to claim 10.

17. A method for manufacturing a semiconductor electronic component or a semiconductor equipment using a cured relief pattern manufactured by the method according to claim 13.
